(19) United States
(12) Patent Application Publication
(10) Pub. No.: US 2024/0162232 A1
(43) Pub. Date: May 16, 2024

(54) INTEGRATED STRUCTURE WITH TRAP RICH REGIONS AND LOW RESISTIVITY REGIONS

(71) Applicant: GlobalFoundries U.S. Inc., Malta, NY (US)

(72) Inventors: Vibhor JAIN, Williston, VT (US); Crystal R. KENNEY, Waterford, NY (US); John J. PEKARIK, Underhill, VT (US)

(21) Appl. No.: 17/985,861

(22) Filed: Nov. 13, 2022

(51) Int. Cl. H01L 27/12; H01L 21/762; H01L 21/84; H01L 23/66

(52) U.S. Cl. CPC H01L 27/1203; H01L 21/76267; H01L 21/76283; H01L 21/84; H01L 23/66; H01L 2223/6672

(57) ABSTRACT

The present disclosure relates to semiconductor structures and, more particularly, to a substrate with trap rich and low resistivity regions and methods of manufacture. The structure includes: a high resistivity semiconductor substrate; an active device over the high resistivity semiconductor substrate; and a low resistivity region floating in the high resistivity semiconductor substrate and which is below the active device.

### BACKGROUND

The present disclosure relates to semiconductor structures and, more particularly, to an integrated structure with trap rich regions (high resistivity regions) and low resistivity regions and methods of manufacture.

BiCMOS integration on high resistivity semiconductor substrates requires different parameters for different devices. These different parameters may not be compatible amongst all of the integrated devices, e.g., circuitry, residing on the same substrate. In the manufacturing process, these different parameters may also result in low yields for other devices.

### SUMMARY

In an aspect of the disclosure, a structure comprises: a high resistivity semiconductor substrate; an active device over the high resistivity semiconductor substrate; and a low resistivity region floating in the high resistivity semiconductor substrate and which is below the active device.

In an aspect of the disclosure, a structure comprises: a handle substrate comprising high resistivity semiconductor material; a buried insulator layer above the handle substrate; a semiconductor layer on the buried insulator layer; an active device over the semiconductor layer; a non-single-crystal semiconductor region in the handle substrate underneath the active device and contacting an underside of the buried insulator layer; and a low resistivity region floating in the handle substrate and which is below the active device.

In an aspect of the disclosure, a method comprises: forming an active device over a high resistivity semiconductor substrate; and forming a low resistivity region floating in the high resistivity semiconductor substrate and which is below the active device.

### BRIEF DESCRIPTION OF THE DRAWINGS

The present disclosure is described in the detailed description which follows, in reference to the noted plurality of drawings by way of non-limiting examples of exemplary embodiments of the present disclosure.

FIG. 1 shows a structure with both a high resistivity region and a low resistivity region under an active device, amongst other features, and respective fabrication processes in accordance with the present disclosure.

FIG. 2 shows an integrated design layout and respective fabrication processes in accordance with the present disclosure.

### DETAILED DESCRIPTION

The present disclosure relates to semiconductor structures and, more particularly, to a structure with a trap rich region (high resistivity region) and a low resistivity region and methods of manufacture. More specifically, the present disclosure is directed to a BiCMOS integrated structure on a high resistivity wafer with trap rich implant regions and low resistivity implant regions. Advantageously, the integration scheme maintains high NPN yield with reduced device to device leakage for BiCMOS integration, in addition to maintaining back end of the line (BEOL) passive device and RF FET performance (e.g., switches). The present disclosure also provides the benefit of radiation hardening of FET devices.

In embodiments, the structure may include an integrated circuit for radiation hardened electronics. The structure includes a high resistivity semiconductor material comprising semiconductor-on-insulator (SOI) technology. The structure includes a region with a high resistivity implant touching a buried insulator material, forming a trap rich layer below RF FETs or BEOL passive devices. A hybrid region may be surrounded by a deep trench isolation structure and includes a low resistivity region below a bipolar device, FET, or diode, etc. Another region includes both a trap rich region and low resistivity region below a logic FET or other active device. Another region with a FET or passive device is completely devoid of both the trap rich region and low resistivity region.

The structure of the present disclosure can be manufactured in a number of ways using a number of different tools. In general, though, the methodologies and tools are used to form structures with dimensions in the micrometer and nanometer scale. The methodologies, i.e., technologies, employed to manufacture the structure of the present disclosure have been adopted from integrated circuit (IC) technology. For example, the structures are built on wafers and are realized in films of material patterned by photolithographic processes on the top of a wafer. In particular, the fabrication of the structure uses three basic building blocks: (i) deposition of thin films of material on a substrate, (ii) applying a patterned mask on top of the films by photolithographic imaging, and (iii) etching the films selectively to the mask. In addition, precleaning processes may be used to clean etched surfaces of any contaminants, as is known in the art. Moreover, when necessary, rapid thermal anneal processes may be used to drive-in dopants or material layers as is known in the art.

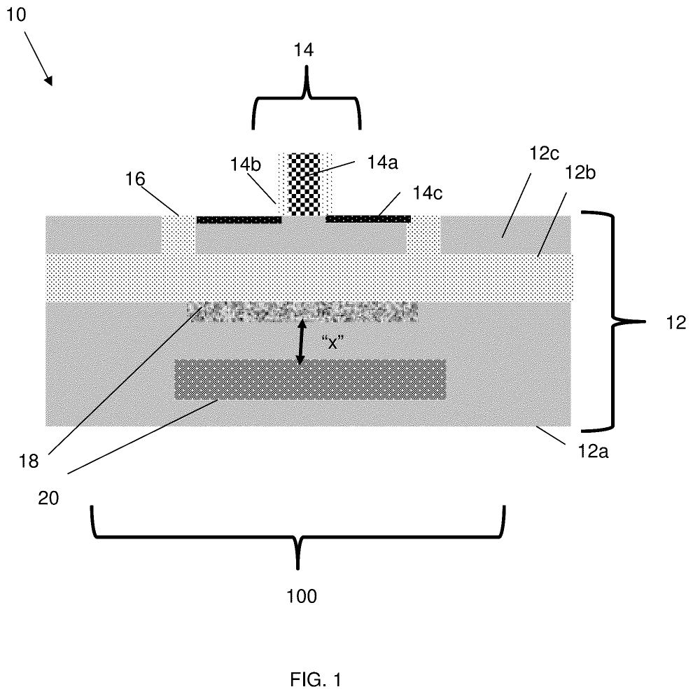

FIG. 1 shows a structure with both a high resistivity region and a low resistivity region under an active device, amongst other features, and respective fabrication processes in accordance with the present disclosure. In particular, the structure 10 includes a device region 100 comprising an active device 14 between shallow trench isolation structures 16. In more specific embodiments, the active device 14 may be a logic device (e.g., FET) for radiation hardened applications. The active device 14 may be provided on a semiconductor substrate 12 as described in more detail herein.

In embodiments, the active device 14 includes a gate electrode 14a surrounded by sidewall spacers 14b. The gate electrode 14a may be any known workfunction metal, e.g., Ti, TiN, TiAl, etc., or a polysilicon material. The sidewall spacers 14b may be an oxide and/or nitride material fabricated using conventional deposition methods, e.g., chemical vapor deposition (CVD), followed by a conventional anisotropic etching process as is known in the art. The active device 14 also includes source and drain regions 14c which are provided in the semiconductor substrate 12 (and more specifically, on a semiconductor-on-insulator substrate). The gate electrode 14a may be provided on a gate dielectric material, e.g., a high-k gate dielectric material, e.g., HfO₂ Al₂O₃, Ta₂O₃, TiO₂, La₂O₃, SrTiO₃, LaAlO₃, ZrO₂, Y₂O₃, Gd₂O₃, and combinations including multilayers thereof.

The device 14 can be fabricated using conventional CMOS processes. For example, in standard CMOS processing, a gate dielectric material and gate electrode material are formed, e.g., deposited, onto the semiconductor substrate 12, followed by a conventional patterning process. An insulator material such as nitride and/or oxide can be deposited on the patterned materials, followed by an anisotropic etching process to form the sidewall spacers 14b. The source and drain regions 14c may be formed by a conventional ion implantation process or an epitaxial growth process with an in-situ doping as is known in the art. It is well understood by those of skill in the art that the source and drain regions 14c could also be formed by using both epitaxial growth and implantation processes such that the top of the source and drain regions 14c is above the top of the semiconductor substrate 12, i.e., top semiconductor layer 12c.

Although not critical to the understanding of the present disclosure, a silicide contact may be formed on the source and drain regions 14c and gate electrode (e.g., polysilicon material). As should be understood by those of skill in the art, the silicide process begins with deposition of a thin transition metal layer, e.g., nickel, cobalt or titanium, over fully formed and patterned semiconductor devices (e.g., doped or ion implanted source and drain regions 14c and respective device (if polysilicon material). After deposition of the material, the structure is heated allowing the transition metal to react with exposed silicon (or other semiconductor material as described herein) in the active regions of the semiconductor device (e.g., source, drain, gate contact region) forming a low-resistance transition metal silicide. Following the reaction, any remaining transition metal is removed by chemical etching, leaving silicide contacts in the active regions of the device. It should be understood by those of skill in the art that silicide contacts will not be required on the devices when a gate structure is composed of a metal material.

Still referring to FIG. 1, the semiconductor substrate 12 may comprise semiconductor-on-insulator (SOI) technology. The semiconductor substrate 12 includes, from bottom to top, a handle substrate 12a, a buried insulator layer 12b, and a top semiconductor layer 12c. The handle substrate 12a may be a high resistivity substrate to provide increased radio frequency (RF) performance. In embodiments, the handle substrate 12a may be a P-semiconductor substrate with a resistivity in the range of about between 1 Kohm-cm to greater than 10 Kohm-cm, as an illustrative example. The handle substrate 12a provides mechanical support to the buried insulator layer 12b and the top semiconductor layer 12c.

The buried insulator layer 12b may include a dielectric material such as silicon dioxide, silicon nitride, silicon oxynitride, boron nitride or a combination thereof. In one preferred embodiment, the buried insulator layer 12b may be a buried oxide (BOX). The buried insulator layer 12b may be formed by a deposition process, such as chemical vapor deposition (CVD), plasma enhanced chemical vapor deposition CVD (PECVD) or physical vapor deposition (PVD). In another embodiment, the buried insulator layer 12b may be formed using a thermal growth process, e.g., thermal oxidation, or an implanting process where oxygen atoms are implanted and annealed into the handle substrate 12a.

The handle substrate 12a and top semiconductor layer 12c may include any appropriate semiconductor material, e.g., Si, Ge, SiGe, SiC, SiGeC, a III-V compound semiconductor, an II-VI compound semiconductor or any combinations thereof. Typically, the handle substrate 12a and the top semiconductor layer 12c comprise a single crystalline semiconductor material, such as, for example, single crystalline silicon with any suitable crystallographic orientation (e.g., a (100), (110), (111), or (001) crystallographic orientation).

Still referring to FIG. 1, an optional non-single-crystal semiconductor region 18 may be formed in the handle substrate 12a. In more specific embodiments, the non-single-crystal semiconductor region 18 may be trap rich region and, more specifically, an amorphous region or polysilicon region. In embodiments, the non-single-crystal semiconductor region 18 may be formed directly underneath and in contact with an underside of the buried insulator layer 12b, underneath the device 14.

In embodiments, the non-single-crystal semiconductor region 18 may reduce the effects of a total ionizing dose (TID). For example, the non-single-crystal semiconductor region 18 can create traps so that the charge carriers formed as a result of ionizing radiation can recombine so that a Vt (or performance) of the device 14 does not change. It should be understood by those of ordinary skill in the art that the effects of total ionizing dose in electronics can include a parametric degradation that leads to device degradation and functional failure. This includes threshold voltage shifts which can alter the way electronics function, such as how they are activated or deactivated. Reduced gain, increased leakage, timing changes and decreased functionality can also occur.

The non-single-crystal semiconductor region 18 may be formed by an implantation process, using a patterned implantation mask. For example, the non-single-crystal semiconductor region 18 may be formed by a blanket argon implant process; although the use of any non-dopant or noble gas is contemplated herein for the implantation process.

As an illustrative, non-limiting example, the handle substrate 12a can be subjected to an argon implant at 300 KeV and a dose of 1×10¹⁵ cm⁻². By way of further illustrative examples, other implant parameters are contemplated herein depending on the desired thickness and depth of the implant region including, e.g., the ion dose may be less than or greater than 1×10¹⁵ cm⁻² or within a range of 1×10¹³ cm⁻² to 5×10¹⁶ cm⁻². Similarly the energy of the implant can be adjusted depending on the desired depth from surface of the trap rich region. The thickness of the non-single-crystal semiconductor region 18 can be adjusted depending on the parameters of the implantation process. In this way, the non-single-crystal semiconductor region 18 may be a high resistivity region, e.g., higher than the resistivity of the handle substrate 12a, which will reduce the TID.

FIG. 1 further shows a low resistivity region 20 in the handle substrate 12a. In embodiments, the low resistivity region 20 may be used to reduce single event upsets. As should be understood by those of skill in the art, the single-event upset (SEU) is a change of state caused by one single ionizing particle (ions, electrons, photons, etc.) striking a sensitive node in a micro-electronic device, e.g., device 14. The state change is a result of the free charge (electron hole pair (EHP)) created by ionization in or close to an important node of a logic element. The error in device output or operation caused as a result of the strike is called an SEU or a soft error.

The low resistivity region 20 may be an implanted region comprising boron, which has a lower resistivity than the handle substrate 12a. For example, the lower resistivity region 20 may be less than 100 Ohm-cm to 0.001 Ohm-cm depending on the implant conditions. In embodiments, the low resistivity region 20 is a floating region (e.g., no electrical connections) that is separated from and makes no contact with the non-single-crystal semiconductor region 18 or the device 14. In embodiments, the low resistivity region 20 may be separated from the non-single-crystal semiconductor region 18 by a high resistivity region of the handle substrate 12a by a distance “X”, where “X” is about 0.5 microns; although other distances are also contemplated herein depending on the desired device performance, as well as the thickness of the handle substrate 12a.

The low resistivity region 20 may be formed by an implantation process using a patterned implantation mask. For example, the low resistivity region 20 may be formed by a blanket boron implant process. As an illustrative, non-limiting example, the handle substrate 12a can be subjected to a boron implant at 400 keV and a dose of 5E11 cm 2. By way of further illustrative examples, other implant parameters are contemplated herein depending on the desired thickness and depth of the implant region including, e.g., the ion dose may be less than or greater than 5E11 cm⁻² or within a range of 5E10 to 1E17 cm⁻². The energy of the implant can be adjust depending on the desired depth of the low resistivity region 20. The thickness of the low resistivity region 20 can be adjusted depending on the parameters of the implantation process.

For both the low resistivity region 20 and the non-single-crystal semiconductor region 18, respective patterned implantation masks may be used to define selected areas exposed for the implantations. The implantation masks may include a layer of a light-sensitive material, such as an organic photoresist, applied by a spin coating process, pre-baked, exposed to light projected through a photomask, baked after exposure, and developed with a chemical developer. Each of the implantation masks has a thickness and stopping power sufficient to block masked areas against receiving a dose of the implanted ions.

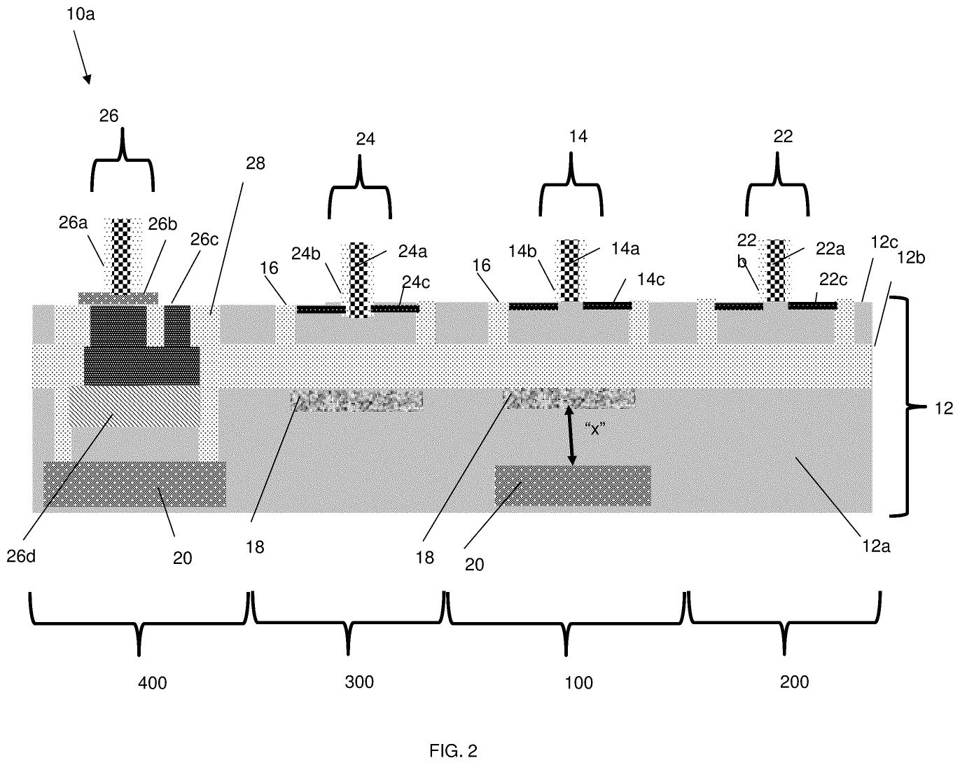

FIG. 2 shows an integrated design layout in accordance with aspects of the present disclosure. In particular, the integrated design layout 10a includes four device regions: device region 100, device region 200, device region 300, and device region 400. As shown in FIG. 2, each of the device regions 100, 200, 300, 400 are provided on the semiconductor substrate 12 comprising the handle substrate 12a, the buried insulator layer 12b and the top semiconductor layer 12c as described with respect to FIG. 1. It should also be recognized that device region 100 is the device region 100 described with respect to FIG. 1.

The device region 200 may include a standard logic device 22. Alternatively, the device region 200 may include a passive device. In the implementation of the standard logic device 22, the logic device 22 includes a gate electrode 22a surrounded by sidewall spacers 22b. The gate electrode 20a may be any known workfunction metal, e.g., Ti, TiN, TiAl, etc., or a polysilicon material. The sidewall spacers 22c may be an oxide and/or nitride material fabricated using conventional deposition methods, e.g., CVD, followed by a conventional anisotropic etching process as is known in the art. The active device 22 also includes source and drain regions 22c which are provided in the semiconductor layer 12c. This also may be a raised source and drain regions 22c formed by epitaxial growth and implantation processes as already described herein. The gate electrode 22a may be provided on a gate dielectric material, e.g., a high-k gate dielectric material, e.g., HfO₂ Al₂O₃, Ta₂O₃, TiO₂, La₂O₃, SrTiO₃, LaAlO₃, ZrO₂, Y₂O₃, Gd₂O₃, and combinations including multilayers thereof. The device region 200 is devoid of any high resistivity region and low resistivity region.

The device region 300 includes a standard RF device or BEOL passive device 24. In this implementation, the standard RF device 24 includes a gate electrode 24a surrounded by sidewall spacers 24b, in addition to source and drain regions 24c. The device region 300 also includes the non-single-crystal semiconductor region 18 formed directly underneath and in contact with an underside of the buried insulator layer 12b, underneath the device 24. The non-single-crystal semiconductor region 18 in device regions 100 and 300 may be formed in the same implantation process with the same patterned mask. As previously disclosed, the low resistivity region 20 may be an implanted region comprising argon. The device region 300, though, is devoid of any low resistivity region.

The device region 400 includes a heterojunction bipolar transistor 26, e.g., NPN. In embodiments, the device region 400 may include other devices such as a diode or passive device. As is known in the art, the heterojunction bipolar transistor 26 includes an emitter 26a, an extrinsic/intrinsic base region 26b, a collector region 26c and a sub-collector region 26d. In embodiments, the collector region 26c is formed over the sub-collector region 26d. The collector region 26c may be Si material, as an example. The sub-collector region 26d may be formed in the handle substrate 12a by an ion implant process, using a patterned mask as is known in the art. The implant can be a n-type dopant, e.g., Arsenic (As), Phosphorus (P) and Sb, among other suitable examples. The extrinsic/intrinsic base region 26b may be a semiconductor material, e.g., SiGe, epitaxially grown on the top semiconductor layer 12c. The emitter 26a may be an N-type semiconductor material epitaxially grown on the intrinsic base region 26b.

The collector region 26c and sub-collector region 26d are isolated within deep trench isolation structures 28. In embodiments, the deep trench isolation structures 28 can be formed by conventional lithography, etching and deposition methods known to those of skill in the art. For example, a resist formed over the top semiconductor layer 12c is exposed to energy (light) and developed utilizing a conventional resist developer to form a pattern (opening). An etching process with a selective chemistry, e.g., reactive ion etching (RIE), will be used to transfer the pattern from the patterned photoresist layer to the top semiconductor layer 12c and handle substrate 12a to form one or more trenches. Following the resist removal by a conventional oxygen ashing process or other known stripants, insulator material can be deposited by any conventional deposition processes, e.g., CVD processes. Any residual material on the surface of the top semiconductor layer 12c can be removed by conventional chemical mechanical polishing (CMP) processes.

Still referring to device region 400, the low resistivity region 20 is formed in the handle substrate 12a under the sub-collector region 26d. In further embodiments, the low resistivity region 20 does not contact the sub-collector region 26d. The low resistivity region 20 may contact the deep trench isolation regions 28 in order to isolate the device 26. The low resistivity region 20 in device regions 100 and 400 may be formed in the same implantation process with the same mask. As previously disclosed, the low resistivity region 20 may be an implanted region comprising boron, which has a lower resistivity than the handle substrate 12a.

The structures can be utilized in system on chip (SoC) technology. The SoC is an integrated circuit (also known as a “chip”) that integrates all components of an electronic system on a single chip or substrate. As the components are integrated on a single substrate, SoCs consume much less power and take up much less area than multi-chip designs with equivalent functionality. Because of this, SoCs are becoming the dominant force in the mobile computing (such as in Smartphones) and edge computing markets. SoC is also used in embedded systems and the Internet of Things.

The method(s) as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed:

1. A structure comprising:
a high resistivity semiconductor substrate;
an active device over the high resistivity semiconductor substrate; and
a low resistivity region floating in the high resistivity semiconductor substrate and which is below the active device.

2. The structure of claim 1, wherein the high resistivity semiconductor substrate comprises a high resistivity handle substrate underneath a buried insulator layer and a top semiconductor layer.

3. The structure of claim 2, wherein the low resistivity region is floating below and not touching the buried insulator layer and the active device in the high resistivity handle substrate, with a high resistivity region between the active device and the low resistivity region.

4. The structure of claim 3, wherein the low resistivity region comprises boron.

5. The structure of claim 3, further comprising a non-single-crystal semiconductor region in high resistivity handle substrate.

6. The structure of claim 5, wherein the non-single-crystal semiconductor region comprises one of amorphous and polycrystalline semiconductor material in contact with an underside of the buried insulator layer and separated from the low resistivity region.

7. The structure of claim 5, wherein the non-single-crystal semiconductor region comprises a trap rich semiconductor region in contact with an underside of the buried insulator layer and separated from the low resistivity region.

8. The structure of claim 5, wherein the active device comprises a logic transistor.

9. The structure of claim 5, further comprising a device over the high resistivity handle substrate and which is devoid of the low resistivity region and the non-single-crystal semiconductor region.

10. The structure of claim 5, further comprising a device over the high resistivity handle substrate and which is devoid of the low resistivity region and includes the non-single-crystal semiconductor region under the device.

11. The structure of claim 5, further comprising a device over the high resistivity handle substrate and which is devoid of the non-single-crystal semiconductor region and includes the low resistivity region under the device.

12. A structure comprising:
a handle substrate comprising high resistivity semiconductor material;
a buried insulator layer above the handle substrate;
a semiconductor layer on the buried insulator layer;
an active device over the semiconductor layer;
a non-single-crystal semiconductor region in the handle substrate underneath the active device and contacting an underside of the buried insulator layer; and
a low resistivity region floating in the handle substrate and which is below the active device.

13. The structure of claim 12, wherein the low resistivity region comprises boron and the non-single-crystal semiconductor region comprises one of amorphous and polycrystalline semiconductor material.

14. The structure of claim 12, wherein the non-single-crystal semiconductor region comprises trap rich semiconductor material in contact with an underside of the buried insulator layer and separated from the low resistivity region.

15. The structure of claim 12, further comprising a second device over the semiconductor layer, wherein the high resistivity semiconductor material under the second device is devoid of the low resistivity region and the non-single-crystal semiconductor region.

16. The structure of claim 15, further comprising a third device over the semiconductor layer, wherein the high resistivity semiconductor material under the third device is devoid of the low resistivity region and includes the non-single-crystal semiconductor region.

17. The structure of claim 16, further comprising a fourth device over the handle substrate, wherein the high resistivity semiconductor material under the fourth device is devoid of the non-single-crystal semiconductor region and includes the low resistivity region.

18. The structure of claim 12, wherein the active device comprises a radiation hardened logic device.

19. The structure of claim 12, wherein the low resistivity region comprises boron.

20. A method comprising:
forming an active device over a high resistivity semiconductor substrate; and
forming a low resistivity region floating in the high resistivity semiconductor substrate and which is below the active device.
